(19) United States
(12) Patent Application Publication
(10) Pub. No.: US 2021/0092840 A1
(43) Pub. Date: Mar. 25, 2021

(54) CONDUCTIVE COMPOSITION, CONDUCTIVE FILM, AND CIRCUIT BOARD USING THE SAME

(71) Applicant: Zhen Ding Technology Co., Ltd., Tayuan (TW)

(72) Inventors: SHENG-FENG CHUNG, Tayuan (TW); CHEN-FENG YEN, Taoyuan (TW); BO-HONG ZHOU, Tayuan (TW)

(21) Appl. No.: 16/683,741

(22) Filed: Nov. 14, 2019

(30) Foreign Application Priority Data
Sep. 23, 2019 (CN) 201910899398.X

(51) Int. Cl. H05K 1/09; C08G 59/00; C08K 9/02; C08K 3/08; C08J 5/18; H05K 3/40; H01B 1/22

(52) U.S. Cl. CPC H05K 1/092; C08G 59/00; C08K 9/02; C08K 3/08; C08J 5/18; H05K 3/4053; H05K 2203/1131; C08K 2201/001; C08K 2201/006; C08K 2003/085; C08K 2003/0837; C08J 2363/00; H01B 1/22

(57) ABSTRACT

A durable but thin-film conductive composition of increased flexibility comprises about 90 parts by weight to about 110 parts by weight of a thermosetting resin, about 900 parts by weight to about 1100 parts by weight of a conductive agent, about 10 parts by weight to about 15 parts by weight of a hardener, and about 0 part by weight to about 50 parts by weight of a thixotropic agent. The disclosure further provides a conductive film formed by heating and curing the conductive composition and a circuit board with several circuit layers joined by the conductive film.

### FIELD

The subject matter herein generally relates to circuit boards, and more particular to a conductive composition, a conductive film using the conductive composition, and a circuit board using the conductive film.

### BACKGROUND

To reduce a size of a circuit board, a through hole is defined on an insulating resin layer of the circuit board, and a conductive film formed on a side of the through hole to electrically connect a first circuit layer above the insulating resin layer and a second circuit layer below the insulating resin layer. The conductive film is usually formed by an electroplating copper process or a conductive paste filling process. However, the electroplating copper process is complicated, and the conductive film formed by the electroplating copper process has low flexibility.

### BRIEF DESCRIPTION OF THE DRAWINGS

Implementations of the present technology will now be described, by way of embodiment, with reference to the attached figures.

FIG. 1 is a cross-sectional view of an embodiment of a circuit board.

FIG. 2 is a flow chart of an embodiment of a method for manufacturing the circuit board of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “comprising,” when utilized, means “including, but not necessarily limited to”; it specifically indicates open-ended inclusion or membership in the so-described combination, group, series, and the like. The term “about” and “approximately” when utilized, means “not only include the numerical value, but also include numbers close to the stated numerical value”.

A conductive composition is disclosed, the composition having high conductivity, good flexibility, and storage stability at room temperature. A conductive film made from the composition is formed by heating and curing the conductive composition. The conductive film can be applied to a circuit board to electrically connect between several stacked circuit layers of the circuit board. The conductive composition comprises about 90 parts by weight to about 110 parts by weight of a thermosetting resin, about 900 parts by weight to about 1100 parts by weight of a conductive agent, about 10 parts by weight to about 15 parts by weight of a hardener, and about 0 part by weight to about 50 parts by weight of a thixotropic agent.

The thermosetting resin has a high flexibility into which conductive agents can be dispersed. The thermosetting resin can be selected from the group consisting of carboxy nitrile rubber modified epoxy resin, butadiene modified epoxy resin, bisphenol-F epoxy resin, and any combination thereof. The modified epoxy resin of the carboxy nitrile rubber modified epoxy resin comprises bisphenol-A epoxy resin, bisphenol-F epoxy resin, and hydride thereof. In one embodiment, the thermosetting resin comprises about 0 part by weight to about 35 parts by weight of the carboxy nitrile rubber modified epoxy resin, about 35 parts by weight to about 38 parts by weight of the butadiene modified epoxy resin, and about 30 parts by weight to about 65 parts by weight of the bisphenol-F epoxy resin.

The conductive agent comprises a first metal powder with a low melting point and a second metal powder with a high melting point. The melting point of the first metal powder is lower than about 180° C., for example, the first metal powder can be tin powder or tin bismuth alloy powder. The melting point of the second metal powder is higher than about 800° C. In one embodiment, the second metal powder comprises metal powders of different shapes, such as spherical silver-coated copper or dendritic silver-coated copper powders. A weight ratio between the second metal powder and the first metal powder is about 1:6 to about 2:3.

In one embodiment, the hardener is a high temperature hardener having the —OH group or a stable hardener at room temperature having a core-shell structure. The hardener is configured for improving a storage stability of conductive composition at room temperature. The high temperature hardener having the —OH group acts as a hardener under high temperature treatment, which is preferably an imidazole-based hardener, such as 2-methylimidazole or 2-ethyl-4-methylimidazole. The active functional groups of the stable hardener at room temperature having core-shell structure start to react only when a reaction temperature reaches a certain level. The stable hardener at room temperature with core-shell structure has a good storage stability. When the reaction temperature is reached, the active functional groups of the stable hardener at room temperature are cross-linked with the reactive functional groups of the thermosetting resin. The stable hardener at room temperature with core-shell structure is preferably that of ASAHI KASEI Co., Ltd., NOVACURE HX-3088, HX-3741, or that of Fuji Chemicals Co., Ltd., Fujicure FXR-1030, FXR-1081. A reactive temperature of the hardener is the same as a heating/curing temperature of the conductive composition, which is preferably about 120° C. to about 205° C.

The thixotropic agent is configured to improve a thixotropy of the conductive composition. The thixotropic agent preferably comprises metal powder having a high specific surface area, which can improve the thixotropy and conductivity of the conductive composition. The thixotropy of the thixotropic agent is about 3 to about 5 (2 rpm/20 rpm). The specific surface area of the metal powder is about 0.3 m²/g to about 0.7 m²/g, a tap density of the metal powder is about 1.05 g/cm³ to about 1.7 g/cm³, and a grain size of the metal powder is about 7 um to about 15 um. The thixotropic agent is preferably dendritic silver-coated copper powder.

The conductive composition further comprises adherence accelerant, fluxing agent, and solvent free active diluent. The adherence accelerant can be any adherence accelerant known in the field, which can be a silane coupling agent, an aromatic or heterocyclic compound, a phosphate eater compound, a polyvalent metal salt or ester, such as titanate or zirconate, an organic polymer resin such as epoxy resin or polyester resin, or a chlorinated polyolefin. The fluxing agent can be any fluxing agent known in the field. The solvent free active diluent is configured to adjust a viscosity of the conductive composition, which can be any solvent free active diluent known in the field.

In the conductive composition in the conductive paste filling process, the thermosetting resin of the conductive composition has high flexibility, the hardener of the conductive composition has storage stability at room temperature, and the thixotropic agent of the conductive composition has high conductivity and thixotropy.

The conductive film is formed by heating and curing the conductive composition. In one embodiment, the conductive film is formed by the transient liquid phase sintering process. After sintering, a continuous phase is formed between the first metal powder with low melting point and the second metal powder with high melting point, thus the conductivity of the conductive film is increased.

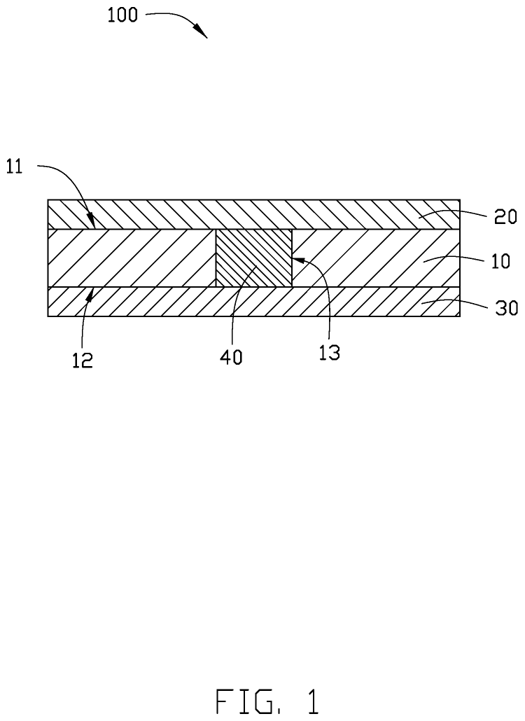

FIG. 1 illustrates a circuit board 100 comprising an insulation layer 10, a first circuit layer 20, a second circuit layer 30, and the conductive film 40. The insulation layer 10 comprises a first surface and a second surface 11 opposite to the first surface 12. The first circuit layer 20 is arranged on the first surface 11, and the second circuit layer 30 is arranged on the second surface 12. The first circuit layer 20 is made of copper. The insulation layer 10 defines a through hole 13, the through hole being through the first surface 11 and the second surface 12. The conductive film 40 is filled in the through hole 13.

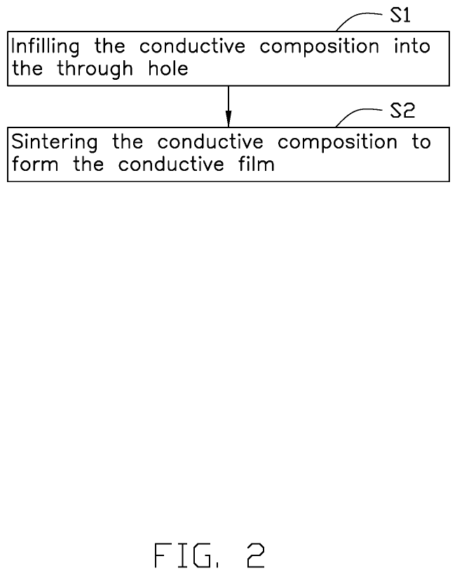

FIG. 2 illustrates a method for manufacturing the circuit board by applying the conductive composition. The conductive composition is first infilled into the through hole by a printing process (block S1). The conductive composition is then sintered with the insulation layer, the first circuit layer, and the second circuit layer by the transient liquid phase sintering process. The conductive composition is sintered to form the conductive film (block S2).

### Embodiment 1

62.5 parts by weight of EPOLLY 8220 (produced by CVC Thermoset Specialties, America), 37.5 parts by weight of GE-24 (produced by CVC Thermoset Specialties, America), 400 parts by weight of spherical silver-coated copper powder, 600 parts by weight of tin bismuth alloy powder, 20 parts by weight of dendritic silver-coated copper powder, and 12.5 parts by weight of Fujicure FXR-1030 (produced by Fuji Chemicals, Japan) are evenly mixed to make the conductive composition.

### Embodiment 2

62.5 parts by weight of EPOLLY 8220 (produced by CVC Thermoset Specialties, America), 37.5 parts by weight of GE-24 (produced by CVC Thermoset Specialties, America), 400 parts by weight of spherical silver-coated copper powder, 600 parts by weight of tin bismuth alloy powder, and 12.5 parts by weight of Fujicure FXR-1030 (produced by Fuji Chemicals, Japan) are evenly mixed to make the conductive composition.

### Embodiment 3

32.5 parts by weight of EPOLLY 8220 (produced by CVC Thermoset Specialties, America), 30 parts by weight of RA840 (produced by CVC Thermoset Specialties, America), 37.5 parts by weight of GE-24 (produced by CVC Thermoset Specialties, America), 400 parts by weight of spherical silver-coated copper powder, 600 parts by weight of tin bismuth alloy powder, 20 parts by weight of dendritic silver-coated copper powder, and 12.5 parts by weight of Fujicure FXR-1030 (produced by Fuji Chemicals, Japan) are evenly mixed to make the conductive composition.

### Embodiment 4

32.5 parts by weight of EPOLLY 8220 (produced by CVC Thermoset Specialties, America), 30 parts by weight of RA840 (produced by CVC Thermoset Specialties, America), 37.5 parts by weight of GE-24 (produced by CVC Thermoset Specialties, America), 100 parts by weight of spherical silver-coated copper powder, 600 parts by weight of tin bismuth alloy powder, 20 parts by weight of dendritic silver-coated copper powder, and 12.5 parts by weight of Fujicure FXR-1030 (produced by Fuji Chemicals, Japan) are evenly mixed to make the conductive composition.

### Embodiment 5

32.5 parts by weight of EPOLLY 8220 (produced by CVC Thermoset Specialties, America), 30 parts by weight of RA840 (produced by CVC Thermoset Specialties, America), 37.5 parts by weight of GE-24 (produced by CVC Thermoset Specialties, America), 400 parts by weight of spherical silver-coated copper powder, 600 parts by weight of tin bismuth alloy powder, 50 parts by weight of dendritic silver-coated copper powder, and 12.5 parts by weight of Fujicure FXR-1030 (produced by Fuji Chemicals, Japan) are evenly mixed to make the conductive composition.

### Embodiment 6

32.5 parts by weight of EPOLLY 8220 (produced by CVC Thermoset Specialties, America), 30 parts by weight of RA840 (produced by CVC Thermoset Specialties, America), 37.5 parts by weight of GE-24 (produced by CVC Thermoset Specialties, America), 400 parts by weight of spherical silver-coated copper powder, 600 parts by weight of tin bismuth alloy powder, 0.5 parts by weight of dendritic silver-coated copper powder (BYK410, produced by BYK-Chmie, GmbH), and 12.5 parts by weight of Fujicure FXR-1030 (produced by Fuji Chemicals, Japan) are evenly mixed to make the conductive composition.

### Embodiment 7

32.5 parts by weight of EPOLLY 8220 (produced by CVC Thermoset Specialties, America), 30 parts by weight of RA840 (produced by CVC Thermoset Specialties, America), 37.5 parts by weight of GE-24 (produced by CVC Thermoset Specialties, America), 400 parts by weight of spherical silver-coated copper powder, 600 parts by weight of tin bismuth alloy powder, 20 parts by weight of dendritic silver-coated copper powder, and 12.5 parts by weight of hardener without core-shell structure (C11Z-A, produced by Shikoku Chemicals, Japan) are evenly mixed to make the conductive composition.

### Embodiment 8

32.5 parts by weight of bisphenol-A epoxy resin (EPON 828, produced by HEXION), 37.5 parts by weight of GE-24 (produced by CVC Thermoset Specialties, America), 400 parts by weight of spherical silver-coated copper powder, 600 parts by weight of tin bismuth alloy powder, 20 parts by weight of dendritic silver-coated copper powder, and 12.5 parts by weight of Fujicure FXR-1030 (produced by Fuji Chemicals, Japan) are evenly mixed to make the conductive composition.

### Comparative Embodiment 1

A commercially-available first conductive composition is used in the comparative embodiment, which comprises 100 parts by weight of resin, 200 parts by weight of copper powder, 800 parts by weight of tin powder, and 10 parts by weight of hardener.

### Comparative Embodiment 2

A commercially-available second conductive composition is used in the comparative embodiment, which comprises 100 parts by weight of resin, 200 parts by weight of copper powder, 800 parts by weight of tin powder, and 20 parts by weight of hardener.

Thixotropy and storage stability at room temperature of the conductive compositions of embodiments 1 to 8 and comparative embodiments 1 and 2 were tested. Thixotropy value was determined by placing a sample in a glass bottle and standing same in a water bath at 23° C. for about 1 hour, followed by measuring of the viscosity at 2 rpm and 20 rpm with a HB-type rotational viscometer, after which the viscosity at 2 rpm was divided by the viscosity at 20 rpm. The storage stability at room temperature was tested by placing a sample at room temperature (25° C.), followed by measuring of a number of days for which the characteristics or state of the sample were unchanged. If the characteristics or state of the sample were changed, the test result was recorded as “NG”. The conductive compositions of embodiments 1 to 8 and comparative embodiments 1 and 2 were used to make the conductive films and the circuit boards. Resistances of the circuit board on the through hole without bending and after applying a 180° bending were tested. Adherence between the conductive film and the insulation layer (adherence to LCP) was tested, and adherence between the conductive film and the circuit layer (adherence to copper layer) was tested. If the adherence was good, the test result was recorded as “O” and if the adherence was bad, the test result was recorded as “Δ”. The results of test are shown in Table 1.

TABLE 1

| | | resistance of | resistance of the | | adherence | storage |
|---|---|---|---|---|---|---|
| | | the circuit | circuit board after | | to | stability at |
| | | board without | applying a 180° | adherence | copper | room |
| | thixotropy | bending (mΩ) | bending (Ω) | to LCP | layer | temperature |
| Embodiment | 3.5 | 25 | 54 | O | O | 7 days |
| 1 | | | | | | |
| Embodiment | 1.5 | 47 | 66 | O | O | 7 days |
| 2 | | | | | | |
| Embodiment | 4.0 | 21 | 31 | O | O | 7 days |
| 3 | | | | | | |
| Embodiment | 4.0 | 130 | 144 | O | O | 7 days |
| 4 | | | | | | |
| Embodiment | 4.5 | 20 | 28 | O | O | 7 days |
| 5 | | | | | | |
| Embodiment | 3.6 | 77 | 92 | O | O | 7 days |
| 6 | | | | | | |
| Embodiment | 3.7 | 24 | 36 | O | O | NG |
| 7 | | | | | | |
| Embodiment | 4.2 | 25 | 123 | O | O | 7 days |
| 8 | | | | | | |
| Comparative | 3.3 | 29 | 88 | Δ | Δ | NG |
| embodiment | | | | | | |
| 1 | | | | | | |
| Comparative | 3.2 | 34 | 96 | Δ | Δ | NG |
| embodiment | | | | | | |
| 2 | | | | | | |

As Table 1 shows, the increases in resistance of the through holes caused by the 180° bending is less for the conductive compositions of embodiments 1 to 8 than it is for the conductive compositions of comparative embodiments 1 and 2. Embodiment 2 shows substantial decreases of thixotropy of the conductive compositions. In addition, the conductive compositions prepared by comparative embodiments 1 and 2 have reduced storage stability at room temperature; the conductive composition of comparative embodiment 1 is suitable for storage at 5° C., the conductive composition of comparative embodiment 2 is suitable for storage at 0° C., whereas the conductive compositions of embodiments 1 to 6 and 7 can be stored at room temperature for up to 7 days. The conductive composition of embodiment 6 shows that, when a metal powder without a high specific surface is used as the thixotropic agent, the resistance of the circuit board on the through hole is increased. The conductive composition of embodiment 7 shows that, when a hardener is used, not being a high temperature hardener with the —OH group or a stable hardener at room temperature with a core-shell structure, the conductive composition reacts easily at room temperature and is suitable for storage at 5° C. . The conductive composition of embodiment 8 shows that, when a bisphenol-A epoxy resin is used as the thermosetting resin of the conductive composition, the resistance of the through hole in the circuit board is greatly increased by the 180° bending.

While the present disclosure has been described with reference to particular embodiments, the description is illustrative of the disclosure and is not to be construed as limiting the disclosure. Therefore, those of ordinary skill in the art can make various modifications to the embodiments without departing from the scope of the disclosure as defined by the appended claims.

1. A conductive composition comprising approximately 90 parts by weight to approximately 110 parts by weight of a thermosetting resin, approximately 900 parts by weight to approximately 1100 parts by weight of a conductive agent, approximately 10 parts by weight to approximately 15 parts by weight of a hardener, and approximately 0 part by weight to approximately 50 parts by weight of a thixotropic agent.

2. The conductive composition of claim 1, wherein the thermosetting resin is selected from the group consisting of carboxy nitrile rubber modified epoxy resin, butadiene modified epoxy resin, bisphenol-F epoxy resin, and any combination thereof.

3. The conductive composition of claim 2, wherein the thermosetting resin comprises approximately 0 part by weight to approximately 35 parts by weight of the carboxy nitrile rubber modified epoxy resin, approximately 35 parts by weight to approximately 38 parts by weight of the butadiene modified epoxy resin, and approximately 30 parts by weight to approximately 65 parts by weight of the bisphenol-F epoxy resin.

4. The conductive composition of claim 1, wherein the conductive agent comprises a first metal powder with a melting point lower than approximately 180° C. and a second metal powder with a melting point higher than approximately 800° C., a weight ratio between the second metal powder and the first metal powder is approximately 1:6 to approximately 2:3.

5. The conductive composition of claim 4, wherein the second metal powder comprises metal powders of different shapes.

6. The conductive composition of claim 1, wherein the hardener is a high temperature hardener having the —OH group or a stable hardener at room temperature having a core-shell structure.

7. The conductive composition of claim 1, wherein the thixotropic agent comprises metal powder having a specific surface area of approximately 0.3 m²/g to approximately 0.7 m²/g.

8. The conductive composition of claim 7, wherein the thixotropic agent is dendritic silver-coated copper powder.

9. A conductive film formed by heating and curing a conductive composition, the conductive composition comprising approximately 90 parts by weight to approximately 110 parts by weight of a thermosetting resin, approximately 900 parts by weight to approximately 1100 parts by weight of a conductive agent, approximately 10 parts by weight to approximately 15 parts by weight of a hardener, and approximately 0 part by weight to approximately 50 parts by weight of a thixotropic agent.

10. The conductive film of claim 9, wherein the thermosetting resin is selected from the group consisting of carboxy nitrile rubber modified epoxy resin, butadiene modified epoxy resin, bisphenol-F epoxy resin, and any combination thereof.

11. The conductive film of claim 10, wherein the thermosetting resin comprises approximately 0 part by weight to approximately 35 parts by weight of the carboxy nitrile rubber modified epoxy resin, approximately 35 parts by weight to approximately 38 parts by weight of the butadiene modified epoxy resin, and approximately 30 parts by weight to approximately 65 parts by weight of the bisphenol-F epoxy resin.

12. The conductive film of claim 9, wherein the conductive agent comprises a first metal powder with a melting point lower than approximately 180° C. and a second metal powder with a melting point higher than approximately 800° C., a weight ratio between the second metal powder and the first metal powder is approximately 1:6 to approximately 2:3.

13. The conductive film of claim 12, wherein the second metal powder comprises metal powders of different shapes.

14. The conductive film of claim 9, wherein the hardener is a high temperature hardener having the —OH group or a stable hardener at room temperature having a core-shell structure.

15. The conductive film of claim 9, wherein the thixotropic agent comprises metal powder having a specific surface area of approximately 0.3 m²/g to approximately 0.7 m²/g.

16. The conductive film of claim 15, wherein the thixotropic agent is dendritic silver-coated copper powder.

17. A circuit board comprising:
a first circuit layer;
a second circuit layer;
an insulation layer sandwiched between the first circuit layer and the second circuit layer, the insulation layer defining a through hole; and
a conductive film formed by heating and curing a conductive composition, the conductive composition comprising approximately 90 parts by weight to approximately 110 parts by weight of a thermosetting resin, approximately 900 parts by weight to approximately 1100 parts by weight of a conductive agent, approximately 10 parts by weight to approximately 15 parts by weight of a hardener, and approximately 0 part by weight to approximately 50 parts by weight of a thixotropic agent.

18. The circuit board of claim 17, wherein the thermosetting resin is selected from the group consisting of carboxy nitrile rubber modified epoxy resin, butadiene modified epoxy resin, bisphenol-F epoxy resin, and any combination thereof.

19. The circuit board of claim 17, wherein the conductive agent comprises a first metal powder with a melting point lower than approximately 180° C. and a second metal powder with a melting point higher than approximately 800° C., a weight ratio between the second metal powder and the first metal powder is approximately 1:6 to approximately 2:3.

20. The circuit board of claim 17, wherein the hardener is a high temperature hardener having the —OH group or a stable hardener at room temperature having a core-shell structure.
